(19) United States
(12) Patent Application Publication
(10) Pub. No.: US 2015/0064629 A1
(43) Pub. Date: Mar. 5, 2015

(54) MANUFACTURING METHOD FOR MICROLENSES

(71) Applicant: VisEra Technologies Company Limited, Hsin-Chu City (TW)

(72) Inventors: Han-Lin WU, Hsin-Chu City (TW); Lin-Ya TSENG, Changhua City (TW); Huang-Jen CHEN, Keelung City (TW); Yu-Kun HSIAO, Hsin-Chu City (TW); Wu-Cheng KUO, Hsin-Chu City (TW)

(73) Assignee: VisEra Technologies Company Limited, Hsin-Chu City (TW)

(21) Appl. No.: 14/011,401

(22) Filed: Aug. 27, 2013

(51) Int. Cl. G03F 7/20

(52) U.S. Cl. CPC G03F 7/20
USPC 430/321

(57) ABSTRACT

A manufacturing method of microlenses includes providing a substrate; forming a microlens material on the substrate; disposing a mask over the microlens material; performing an exposure process by a radiant beam emitted to the microlens material via the mask; performing a developing process on the microlens material; and forming microlenses by performing a reflow process on the microlens material.

### BACKGROUND OF THE INVENTION

1. Field of the Invention

The invention relates to a manufacturing method for microlenses, and in particular, to a manufacturing method for microlenses using a mask.

2. Description of the Related Art

Image sensors for cameras usually have microlenses disposed thereon to increase the sensing efficacy of the image sensors. A conventional manufacturing method for microlenses utilizes a binary mask. However, the microlenses made by the conventional manufacturing method have spherical surfaces, which may decrease the image quality of the image sensor.

In addition, side lobes may be caused on the microlenses made by the conventional manufacturing method, and the image quality of the image sensor may be decreased, too.

### BRIEF SUMMARY OF THE INVENTION

To solve the problems of the prior art, the invention provides a mask for manufacturing microlenses with aspherical surfaces.

The invention provides a manufacturing method for microlenses including: providing a substrate; forming a microlens material on the substrate; disposing a mask over the microlens material; performing an exposure process by a radiant beam emitted to the microlens material via the mask; performing a developing process on the microlens material; and performing a reflow process on the microlens material.

The invention provides a manufacturing method for microlenses including: providing a microlens material; disposing a mask over the microlens material, wherein the mask comprises a plurality of phase shift layers and a plurality of shading layers respectively disposed on the phase shift layers; performing an exposure process by a radiant beam emitted to the microlens material via the mask, wherein the phase shift layers allow 3% to 5% radiation to the microlens material; performing a developing process on the microlens material; and performing a reflow process on the microlens material.

The invention provides a mask for manufacturing microlenses including a transparent substrate, a plurality of phase shift layers, and a plurality of shading layers. The phase shift layers are arranged in an array on the transparent substrate. The shading layers are respectively disposed on the phase shift layers. An area of each of the phase shift layers is 1.2 to 2.5 times that of each of the shading layers.

In conclusion, the microlenses made by the manufacturing method with mask have aspherical surfaces, and thus the image quality of an image sensor with the microlenses is improved. Moreover, side lobes caused on the microlenses may be prevented, and thus the image quality is further improved.

### BRIEF DESCRIPTION OF THE DRAWINGS

The invention can be more fully understood by reading the subsequent detailed description and examples with references made to the accompanying drawings, wherein:

FIG. 1 is a bottom view of a mask according to the present disclosure;

FIG. 2 is a cross-sectional view of the mask according to the present disclosure;

FIG. 3 is a flow chart of a manufacturing method for microlenses according to the present disclosure;

FIG. 4 is a cross-sectional view of a substrate and a microlens material before an exposure process of the manufacturing method for microlenses;

FIG. 5 is a cross-sectional view of the manufacturing method for microlenses after the exposure process according to a first embodiment;

FIG. 6 is a cross-sectional view of the substrate and the microlens material after a developing process of the manufacturing method for microlenses according to the first embodiment;

FIG. 7 is a cross-sectional view of the substrate and microlenses according to the first embodiment of the present disclosure;

FIG. 8 is a top view of the substrate and the microlenses according to the first embodiment of the present disclosure;

FIG. 9 is a cross-sectional view of the substrate and a microlens material after a developing process of the manufacturing method for microlenses according to a second embodiment;

FIG. 10 is a cross-sectional view of the substrate and microlenses according to the second embodiment of the present disclosure; and

FIG. 11 is a top view of the substrate and the microlenses according to the second embodiment of the present disclosure.

### DETAILED DESCRIPTION OF THE INVENTION

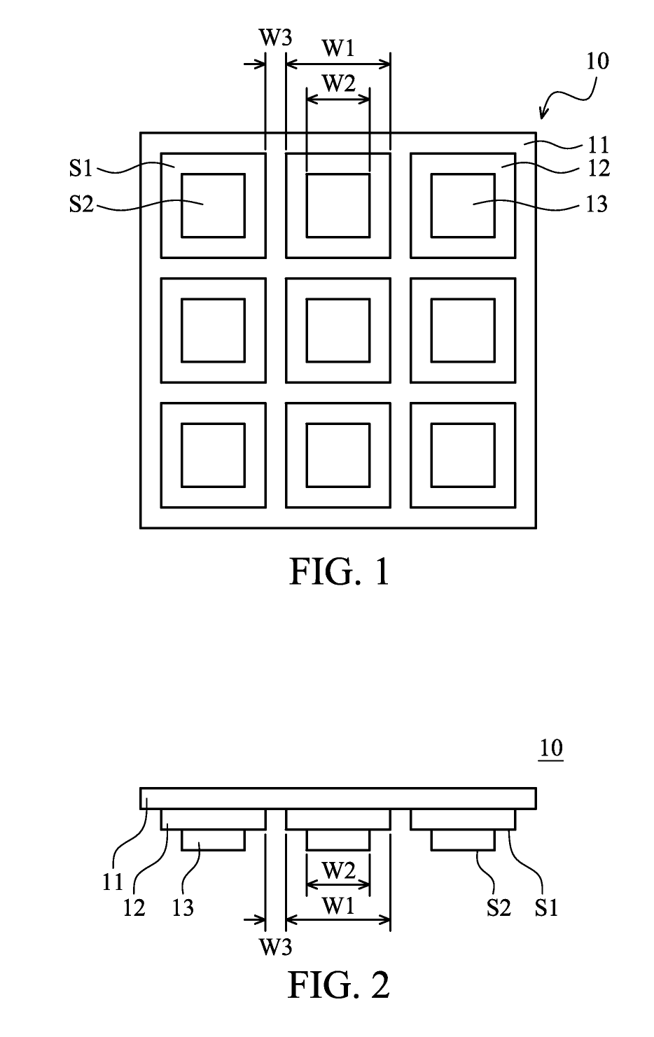

FIG. 1 is a bottom view of a mask 10 according to the present disclosure. FIG. 2 is a cross-sectional view of the mask 10 according to the present disclosure. In this embodiment, the mask 10 is an attenuated-rim mask. The mask 10 includes a transparent substrate 11, a plurality of phase shift layers 12, and a plurality of shading layers 13. The phase shift layers 12 are arranged in an array on the transparent substrate 11. The shading layers 13 may include Cr, and are respectively disposed on the center of the phase shift layers 12.

The transmittance of the transparent substrate 11 is at least greater than 90%, and the transmittance of the shading layers 13 is 0% or lower than 1%. The phase shift layers allow 3% to 5% radiation to the microlens material. Each of the phase shift layers 12 and the shading layers 13 is square.

An area S1 of each of the phase shift layers 12 is 1 to 64 times that of the area S2 of each of the shading layers 13. In this embodiment, the area S1 of each of the phase shift layers 12 is 1.2 to 2.5 times that of the area S2 of each of the shading layers 13. A width W1 of each of the phase shift layers 12 is 1 to 8 times the width W2 of each of the shading layers 13. In this embodiment, the width W1 of each of the phase shift layers 12 is 1 to 1.6 times the width W2 of each of the shading layers 13.

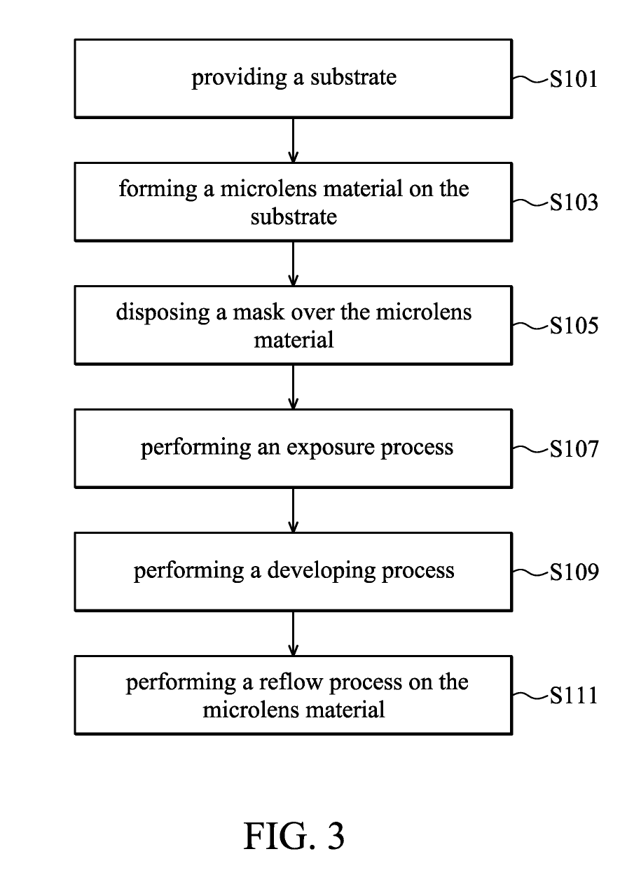

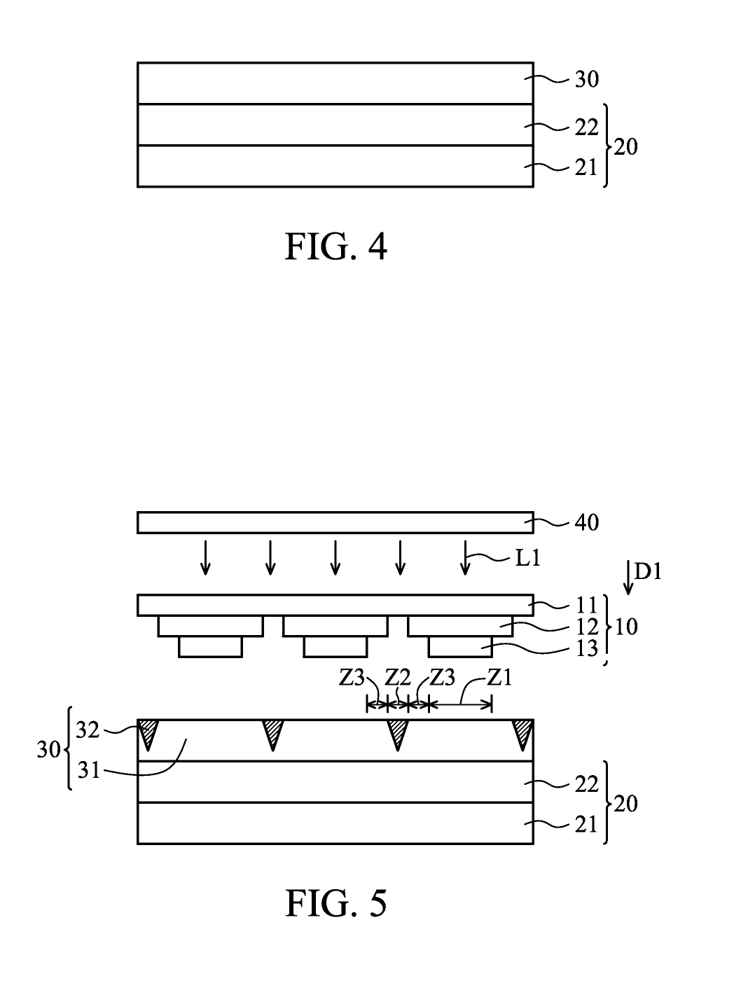

FIG. 3 is a flow chart of a manufacturing method for microlenses according to the present disclosure. FIG. 4 is a cross-sectional view of a substrate 20 and a microlens material 30 before an exposure process of the manufacturing method for microlenses. In step S101, the substrate 20 is provided. The substrate 20 includes a wafer 21 and an image sensor 22 disposed on the wafer 21. In step S103, the microlens material 30 is formed on the image sensor 22 of the substrate 20. In this embodiment, the microlens material 30 is photoresist.

FIG. 5 is a cross-sectional view of the manufacturing method for microlenses after the exposure process according to a first embodiment. In step S105, the mask 10 is disposed over the microlens material 30, and a light source 40 is disposed over the mask 10. In step S107, an exposure process is performed. An exposure dose of the exposure process is between 7000 J/um and 9000J/um.

The light source 40 emits a radiant beam L1 along a direction D1 to the mask 10, and the radiant beam L1 may be an I-line (365 nm). The phase shift layers allow 3% to 5% radiation to the microlens material. After the light source 40 passes through the mask 10 and then emits to a part of the microlens material 30, the microlens material 30 forms unexposed portions 31 and exposed portions 32. The unexposed portions 31 are not emitted by the radiant beam L1, and the exposed portions 32 are emitted by the radiant beam L1. As shown in FIG. 5, the exposed portions 32 do not pass through the unexposed portion 31 along the direction Dl.

In particular, the microlens material 30 has zones Z1 under the shading layer 13, zones Z2 under an exposed part, facing the microlens material 30, of the transparent substrate 11, and zones Z3 under an exposed part, facing the microlens material 30, of the phase shift layer 12. A part of the radiant beam L1 is blocked by the shading layer 13, and the zones Z1 are not emitted by the radiant beam L1. When the radiant beam L1 passes through the phase shift layer 12, the phase of the radiant beam L1 is changed. The radiant beam L1 passing through the phase shift layer 12 may interfere with the radiant beam L1 without passing through the phase shift layer 12. Thus, the energy of the radiant beam L1 emitted on the microlens material 30 is gradually decreased from zones Z2 to zones Z3, and a cross-sectional surface of the exposed portion 32 is a V shape.

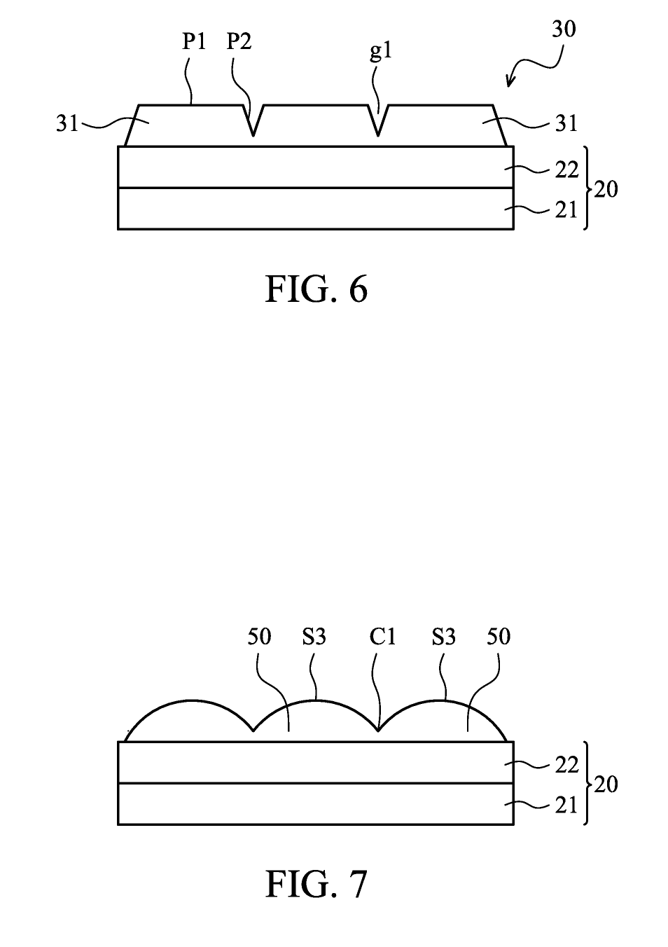

FIG. 6 is a cross-sectional view of the substrate 20 and the microlens material 30 after a developing process of the manufacturing method for microlenses according to the first embodiment. In step S109, a developing process is performed on the microlens material 30. The exposed portion 32 is removed by the developing process, and a groove g1 is formed on the unexposed portion 31. The unexposed portion 31 has flat planes P1 on the top thereof. The groove g1 is a V shape and has inclined walls P2 adjacent to the flat planes P1.

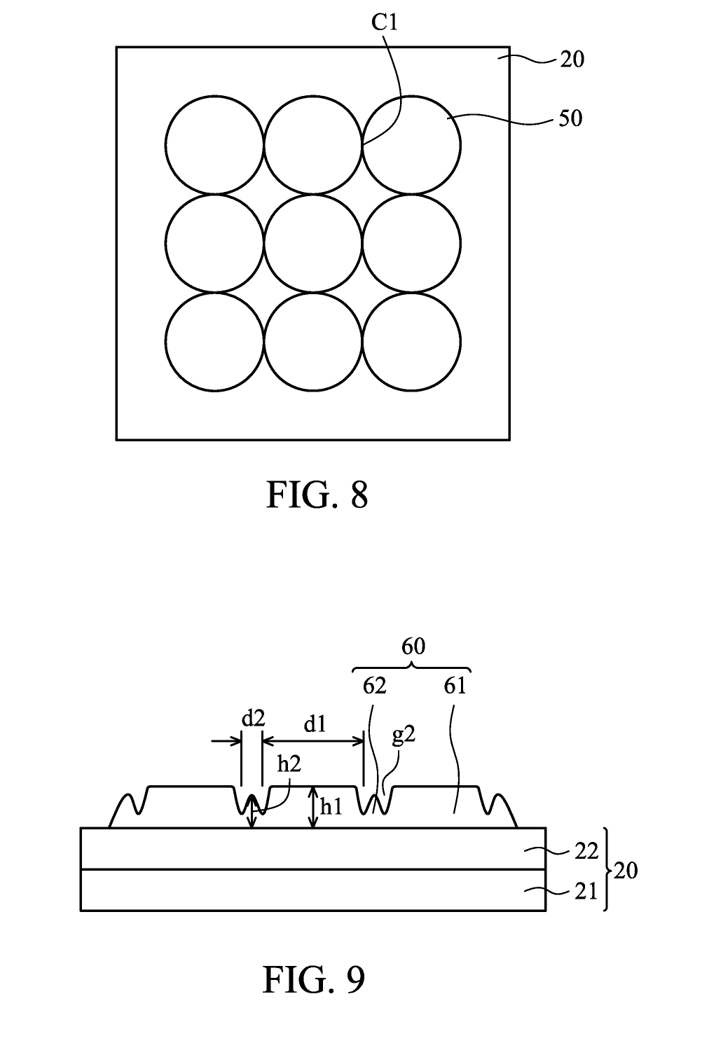

In the step 111, a reflow process is performed on the microlens material 30, and the microlens material 30 is to form the microlenses 50 as shown in FIG. 7. The temperature of the reflow process may be from 150° C. to 190° C. FIG. 7 is a cross-sectional view of the substrate 20 and the microlenses 50 according to the first embodiment of the present disclosure. FIG. 8 is a top view of the substrate 20 and the microlenses 50 according to the first embodiment of the present disclosure. In the embodiment, the microlenses 50 are aspherical microlenses. The microlenses 50 are arranged in an array on the image sensor 22, and two adjacent microlenses 50 are connected to each other. Each of the microlenses 50 has an aspherical surface S3, and two adjacent aspherical surfaces S3 are connected to each other. An inflection point C1 is located between two adjacent and connected aspherical surfaces S3.

FIG. 9 is a cross-sectional view of the substrate 20 and a microlens material 60 after a developing process of the manufacturing method for microlenses according to a second embodiment. In the second embodiment, the exposure dose of the exposure process is between 2000 J/um and 4000 J/um, which is lower than the first embodiment. After a developing process, a groove g2 is formed on the microlens material 60 to make the microlens material 60 have main portions 61 and sub-portions 62. A cross-sectional surface of the groove g2 is a W shape.

The sub-portions 62 are between two adjacent main portions 61, and the main portions 61 are connected to adjacent sub-portions 62. The thickness h1 of the main portion 61 is greater than the thickness h2 of the sub-portion 62, and the width d1 of the main portion 61 is greater than the width d2 of the sub-portion 62.

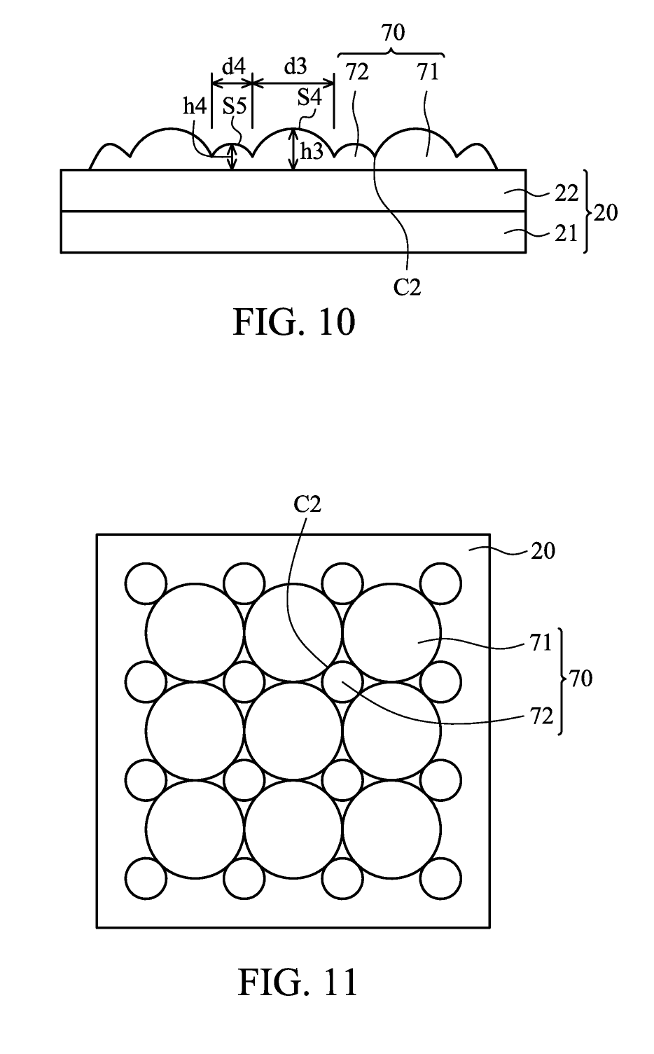

FIG. 10 is a cross-sectional view of the substrate 20 and microlenses 70 according to the second embodiment of the present disclosure. FIG. 11 is a top view of the substrate 20 and the microlenses 70 according to the second embodiment of the present disclosure. After a reflow process, the microlenses 70 comprise a plurality of first microlenses 71 and a plurality of second microlenses 72, which may be aspherical microlenses. The first microlenses 71 are connected to adjacent second microlenses 72. Each of the first microlenses 71 has a first aspherical surface S4, and each of the second microlenses 72 has a second aspherical surface S5. The first aspherical surface S4 are connected to the second aspherical surface S5. An inflection point C2 is located between the two adjacent and connected first aspherical surface S4 and second aspherical surface S5.

The diameter d3 of each of the first microlenses 71 is greater than the diameter d4 of each of the second microlenses 72. In the embodiment, the diameter d3 of each of the first microlenses 71 is two times the diameter d4 of each of the second microlenses 72.

In conclusion, the microlenses made by the manufacturing method with mask have aspherical surfaces, and thus the image quality of the image sensor with the microlenses is improved. Moreover, side lobes caused on the microlenses may be prevented, and thus the image quality is further improved.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A manufacturing method for microlenses, comprising:
providing a substrate;
forming a microlens material on the substrate;
disposing a mask over the microlens material;
performing an exposure process by a radiant beam emitted to the microlens material via the mask;
performing a developing process on the microlens material;
forming a groove on the microlens material to make the microlens material have a plurality of main portions and a sub-portion connected to the main portions after the developing process, wherein a cross-sectional surface of the groove is a W shape, the thickness of the main portion is greater than the thickness of the sub-portion, and the width of the main portion is greater than the width of the sub-portion; and
performing a reflow process on the microlens material.

2. The manufacturing method for microlenses as claimed in claim 1, wherein the mask comprises a transparent substrate, a plurality of phase shift layers arranged in an array on the transparent substrate, and a plurality of shading layers respectively disposed on the phase shift layers, wherein an area of each of the phase shift layers exceeds that of each of the shading layers.

3. The manufacturing method for microlenses as claimed in claim 2, wherein the area of each of the phase shift layers is 1.2 to 64 times that of each of the shading layers.

4. The manufacturing method for microlenses as claimed in claim 2, wherein the width of each of the phase shift layers is 1 to 8 times that of each of the shading layers.

5. The manufacturing method for microlenses as claimed in claim 2, wherein each of the phase shift layers and the shading layers is square.

6. The manufacturing method for microlenses as claimed in claim 2, wherein a transmittance of the phase shift layers is from 3% to 5%.

7. The manufacturing method for microlenses as claimed in claim 1, wherein an exposure dose of the exposure process is between 7000 J/um and 9000 J/um.

8. The manufacturing method for microlenses as claimed in claim 1, further comprising: forming a plurality of aspherical microlenses after the reflow process.

9-10. (canceled)

11. The manufacturing method for microlenses as claimed in claim 1, further comprising: forming a plurality of first microlenses from the main portions and a second microlens, connected to the first microlenses, from the sub-portion after the reflow process, wherein the diameter of each of the first microlenses exceeds that of each of the second microlenses.

12. The manufacturing method for microlenses as claimed in claim 11, wherein the diameter of each of the first microlenses exceeds two times that of each of the second microlenses.

13. The manufacturing method for microlenses as claimed in claim 11, wherein an exposure dose of the exposure process is between 2000 J/um and 4000 J/um.

14. The manufacturing method for microlenses as claimed in claim 1, wherein the substrate comprises a wafer and an image sensor disposed on the wafer, wherein the microlens material is formed on the image sensor.

15. A manufacturing method for microlenses, comprising:
providing a microlens material;
disposing a mask over the microlens material, wherein the mask comprises a plurality of phase shift layers and a plurality of shading layers respectively disposed on the phase shift layers;
performing an exposure process by a radiant beam emitted to the microlens material via the mask, wherein the phase shift layers allow 3% to 5% radiation to the microlens material;
performing a developing process on the microlens material;
forming a groove on the microlens material to make the microlens material have a plurality of main portions and a sub-portion connected to the main portions after the developing process, wherein a cross-sectional surface of the groove is a W shape, the thickness of the main portion is greater than the thickness of the sub-portion, and the width of the main portion is greater than the width of the sub-portion; and
performing a reflow process on the microlens material.

16. The manufacturing method for microlenses as claimed in claim 15, wherein the width of each of the phase shift layers is 1 to 1.6 times that of each of the shading layers, and an area of each of the phase shift layers is 1.2 to 2.5 times that of each of the shading layers.

17. The manufacturing method for microlenses as claimed in claim 15, wherein each of the phase shift layers and the shading layers is square.

18. The manufacturing method for microlenses as claimed in claim 15, wherein the mask is an attenuated-rim mask, and the microlens material is photoresist.

19. The manufacturing method for microlenses as claimed in claim 15, further comprising: forming a plurality of aspherical microlenses after the reflow process.

20. The manufacturing method for microlenses as claimed in claim 15, further comprising: forming a plurality of first microlenses from the main portions and a second microlens, connected to the first microlenses, from the sub-portion after the reflow process, wherein the diameter of each of the first microlenses exceeds that of the second microlenses.
